(19) United States
(12) Patent Application Publication
(10) Pub. No.: US 2026/0063997 A1
(43) Pub. Date: Mar. 5, 2026

(54) METHOD FOR MANUFACTURING MEMBER WITH RECESS STRUCTURE AND MEMBER WITH RECESS STRUCTURE

(71) Applicant: AGC INC., Tokyo (JP)

(72) Inventors: Yoshitaka ONO, Tokyo (JP); Kohei SANO, Tokyo (JP); Yasuo HAYASHI, Tokyo (JP)

(73) Assignee: AGC INC., Tokyo (JP)

(21) Appl. No.: 19/385,936

(22) Filed: Nov. 11, 2025

Related U.S. Application Data
(63) Continuation of application No. PCT/JP2024/012084, filed on Mar. 26, 2024.

(30) Foreign Application Priority Data
May 31, 2023 (JP) 2023-089319

(51) Int. Cl. G03F 7/038; G03F 7/16; G03F 7/20; H01L 21/311

(52) U.S. Cl. CPC G03F 7/038; G03F 7/162; G03F 7/2004

(57) ABSTRACT

A method comprises a step of placing a catalytic material in a first area on a first surface of an object to be processed, in which: the first surface is made of an element of which a boiling point of a fluoride is 550° C. or lower; the catalytic material contains an organic compound containing a polar functional group, and the catalytic material includes, in a cross-sectional view, a first side surface having a first height H1 and a second side surface having a second height H2, the first and second side surfaces being opposed to each other, in which H1>H2>0 μm; a step of irradiating the catalytic material with irradiation light containing deep ultraviolet light having a wavelength of 380 nm or shorter; and a step of exposing the object to be processed to a fluorine-containing gas at 80° C. or higher.

### INCORPORATION BY REFERENCE

This application is based upon and claims the benefit of priority from Japanese patent application No. 2023-089319, filed on May 31, 2023, and PCT application No. PCT/JP2024/012084 filed on Mar. 26, 2024, the disclosure of which is incorporated herein in its entirety by reference.

### BACKGROUND

There are needs for a microfabrication technique by which a microscopic recess structure can be formed on the surface of a sample in various fields. As such a microfabrication technique, various methods have been proposed and put into practical use in the past.

One of such microfabrication techniques is a dry etching method, in which a surface of a sample is etched by using a reactive material such as a reactive gas, ions, and/or radicals.

For example, in a reactive ion etching (RIE) method typified by inductive coupled plasma-RIE (ICP-RIE: Inductive Coupled Plasma-RIE), etching is performed by bringing an etching gas into a plasma state and striking the plasma gas against a sample. It has been reported that such an RIE method makes it possible to perform extremely microscopic fabrication on a sample (e.g., Xiao Li, King Yuk Chan and Rodica Ramer, “Fabrication of Through via Holes in Ultra-Thin Fused Silica Wafers for Microwave and Millimeter-Wave Applications,” Micromachines, 2018, 9, 138).

### SUMMARY

In the field of microfabrication techniques, in view of creation and the like of new optical members, it is desirable to be able to form recess structures having various shapes on surfaces of objects to be processed.

However, there is a problem that it is difficult to form a recess structure having a complicated shape by using the above-described RIE method.

For example, Japanese Unexamined Patent Application Publication No. 2012-42515 discloses a method for manufacturing, by using the above-described RIE method, a recess structure in which an extension axis of a surface of an object to be processed is obliquely inclined with respect to the perpendicular line of the surface.

However, because of the etching characteristics of the RIE method, etching is performed more effectively on the opening side of the recess structure than on the bottom surface side thereof. Therefore, there is a tendency that the recess structure is wider near the opening, so that it is difficult to accurately form a recess structure having a width uniform along the depth direction.

Further, in the RIE method, because of its characteristics, a mask material disposed above the upper part of the objects to be processed is also etched at the same time. Since the cross section of the mask material is usually rectangular or trapezoidal, the shape of the mask material changes when the etching is performed in an oblique direction. Therefore, the problem that etching is performed more effectively on the opening side of the recess structure than on the bottom surface side thereof also occurs due to the above-described cause.

Further, it is not easy to form a recess structure having a curved form along the depth direction by using the method described in Japanese Unexamined Patent Application Publication No. 2012-42515.

The present invention has been made in view of the above-described background, and an object thereof is to provide a manufacturing method capable of relatively easily forming a recess structure inclined in a predetermined direction in a member. Further, another object of the present invention is to provide a member having such a recess structure.

The present invention provides
a method for manufacturing a member with a recess structure, comprising:
(1) a step of placing a catalytic material in a first area on a first surface of an object to be processed, in which
the first surface is made of an element of which a boiling point of a fluoride is 550° C. or lower,
the catalytic material contains an organic compound containing a polar functional group, and
the catalytic material includes, in a cross-sectional view of the catalytic material, i.e., in cross section perpendicular to the first surface, a first side surface having a first height H1 and a second side surface having a second height H2, the first and second side surfaces being opposed to each other, in which H1>0 μm, H2≥0 μm, and the height H1 is higher than the height H2;
(2) a step of irradiating the catalytic material with irradiation light containing deep ultraviolet light having a wavelength of 380 nm or shorter; and
(3) a step of exposing the object to be processed to a fluorine-containing gas at 80° C. or higher, wherein
a recess structure is formed below the first area after the step (3), and the recess structure has, in the cross-sectional view, at a center of the first area, a shape inclined toward the second side surface from a perpendicular line dropped from the first surface.

Further, the present invention also provides
a member with a recess structure on a first surface, wherein
the first surface contains at least one element selected from the group consisting of B, C, Si, P, S, Ti, V, Cr, Ge, As, Se, Nb, Mo, Tc, Ru, Rh, Sn, Sb, Te, I, Ta, W, Re, Os, Ir, Pt, and Au,
the recess structure comprises an opening formed in the first surface, a bottom surface, and a sidewall connecting the opening and the bottom surface,
the recess structure has a curved shape in a cross-sectional view of the catalytic material, i.e., in cross section perpendicular to the first surface,
a ratio P2/P1 of a size P2 of the bottom surface to a size P1 of the opening is in a range of 0.99 or larger, and smaller than 1.1, and
a center of the bottom surface is deviated from an extension axis extending from a center of the opening in a direction perpendicular to the first surface.

According to the present invention, it is possible to provide a manufacturing method capable of relatively easily forming a recess structure inclined in a predetermined direction in a member. Further, according to the present invention, it is also possible to provide a member having such a recess structure.

The above and other objects, features and advantages of the present disclosure will become more fully understood from the detailed description given hereinbelow and the accompanying drawings.

### BRIEF DESCRIPTION OF DRAWINGS

FIG. 1 schematically shows a reaction mechanism that can occur on a first surface of an object to be processed when its organic compound has no polar functional group;

FIG. 2 schematically shows a reaction mechanism that can occur on a first surface of an object to be processed when its organic compound has a polar functional group:

FIG. 3 schematically shows a reaction mechanism that can occur on a first surface of an object to be processed when its organic compound has another type of polar functional group:

FIG. 4 is a graph showing a relationship between a processing temperature and an etching reaction rate when hydrogen fluoride (HF) gas etching is performed on glass:

FIG. 5 is a cross-sectional diagram schematically showing one process in a “basic etching technique”:

FIG. 6 is a cross-sectional diagram schematically showing one process in the “basic etching technique”:

FIG. 7 is a cross-sectional diagram schematically showing a state in which a pattern of catalytic material is set on a first surface of an object to be processed in a method according to an embodiment of the present invention:

FIG. 8 is a cross-sectional diagram schematically showing a state in which etching proceeds on the first surface of the object to be processed in a method according to an embodiment of the present invention:

FIG. 9 is a cross-sectional diagram schematically showing a state in which etching proceeds on the first surface of the object to be processed in a method according to an embodiment of the present invention:

FIG. 10 schematically shows a flow of a method for manufacturing a member with a recess structure according to an embodiment of the present invention:

FIG. 11 is a perspective view schematically showing a state in which a catalytic material is placed on an object to be processed in a method for manufacturing a member with a recess structure according to an embodiment of the present invention:

FIG. 12 is a cross-sectional diagram schematically showing a cross section taken along a line I-I shown in FIG. 11:

FIG. 13 is a cross-sectional diagram schematically showing an example of an object to be processed after an etching process is performed in a method for manufacturing a member with a recess structure according to another embodiment of the present invention:

FIG. 14 is a perspective view of a member according to an embodiment of the present invention:

FIG. 15 is a schematic cross-sectional diagram of the member according to the embodiment of the present invention shown in FIG. 14, taken along a line II-II shown therein:

FIG. 16 schematically shows a form of a surface of a sidewall of a recess structure in a member according to an embodiment of the present invention:

FIG. 17 schematically shows a cross section of a catalytic material formed in an embodiment of the present invention:

FIG. 18 is a photograph showing an example of a cross section of a recess structure according to an embodiment of the present invention (Sample 1):

FIG. 19 is a photograph showing an example of a cross section of a recess structure according to another embodiment of the present invention (Sample 2):

FIG. 20 is a photograph showing an example of a cross section of a recess structure according to still another embodiment of the present invention (Sample 3); and

FIG. 21 is a photograph showing an example of a cross section of a recess structure according to still another embodiment of the present invention (Sample 4).

### DESCRIPTION OF EMBODIMENTS

Embodiments according to the present invention will be described hereinafter.

### (Basic Etching Technique)

As described above, in the RIE method in the related art, there is a problem that it is difficult to manufacture a member with a recess structure having a complicated shape along the depth direction.

In order to cope with such a problem in the related art, the inventors of the present application have earnestly conducted research and development, and have found a microfabrication technique by which it is possible to form a recess structure having a complicated shape, in particular, a curved shape, along the depth direction.

For the better understanding of a method for manufacturing a member according to an embodiment of the present invention, firstly, a microfabrication technique that has been developed by the inventors of the present application up to this point (hereinafter referred to as a “basic etching technique”) will be described.

The basic etching technique includes a process in which an object to be processed with a catalytic material placed on its first surface is exposed to a fluorine-containing gas at a processing temperature of 80° C. or higher (hereinafter referred to as an “etching process”). As will be described in detail later, in the basic etching technique, it is possible to, by performing the above-described “etching process”, selectively etch the area where the catalytic material is placed (hereinafter referred to as a “covered area”) on the first surface of the object to be processed.

Further, in the basic etching technique, the etching rate in the subsequent etching process is controlled by irradiating the catalytic material with specific irradiation light before the etching process is performed on the object to be processed.

The role of the catalytic material in the basic etching technique and the effect of the processing temperature will be described hereinafter.

Note that although the following description is based on a mechanism that is currently presumed, actual phenomena may occur based on other mechanisms.

### (Role of Catalytic Material)

In the basic etching technique, the catalytic material contains an organic compound containing a polar functional group. It is considered that such an organic compound containing a polar functional group has a role of lowering the activation energy of the formation of a fluoride on the surface of the object to be processed.

This role will be described hereinafter with reference to FIGS. 1 to 3. FIGS. 1 to 3 schematically show how the reaction proceeds on the surface of the object to be processed on which the catalytic material is placed.

Note that in the following description, it is assumed, as an example, that the object to be processed is made of SiO₂, and that the surface to be processed (first surface) of the object to be processed is hydrogen-terminated.

Firstly, FIG. 1 schematically shows an etching mechanism assumed on the first surface of the object to be processed when its organic compound has no polar functional group.

When a hydrogen fluoride (HF) gas is supplied from the environment to an area in which the catalytic material is placed, i.e., to the “covered area”, on the surface of SiO₂, of which the object to be processed is made, the HF molecule (a) makes a nucleophilic attack on the Si atom (b) as expressed by the below-shown Formula (i).

However, in order to make the Si atom (b) react with the F atom on the surface of the object to be processed, it is necessary that the OH group (c) on the surface interact with the H atom of the HF molecule (a), and the H—F bond be thereby weakened as expressed by Formula (ii). That is, unless energy for breaking the H—F bond in the HF molecule (a) is supplied, the Si—F bond (d), which involves the elimination of H₂O (g) as expressed by Formula (iii), is not formed.

However, in this reaction system, there is no material that contributes to the decrease in the activation energy of the Si—F bond (d). Therefore, no meaningful etching reaction proceeds in the covered area.

Note that in this system, the etching rate tends to increase in the part where the object to be processed is in direct contact with the HF gas, i.e., in the area where no catalytic material is placed (hereinafter referred to as an “uncovered area”) on the surface as in the ordinary mask pattern process.

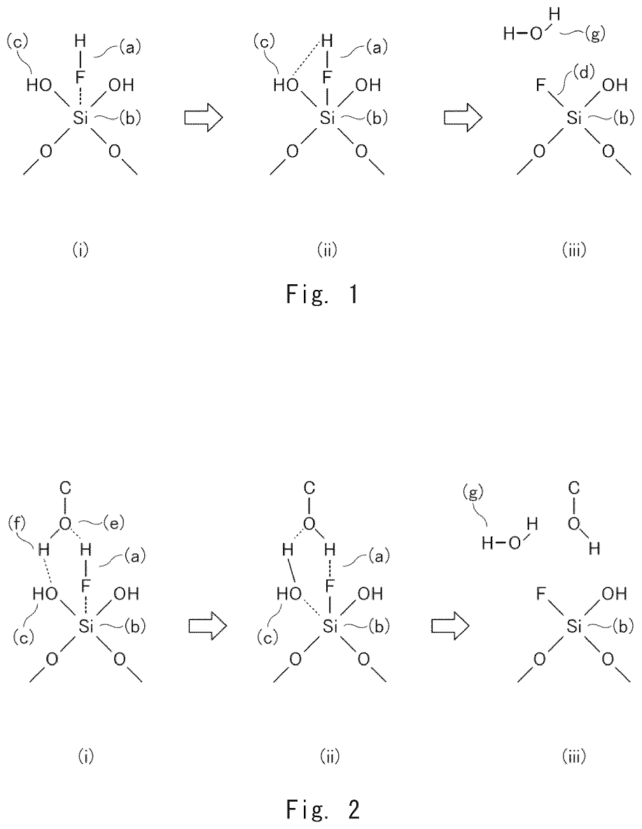

Meanwhile, FIG. 2 schematically shows a reaction mechanism on the first surface of the object to be processed when its organic compound has a polar functional group. In this example, it is assumed that the polar functional group is a hydroxy group.

Even in this case, when an HF gas is supplied from the environment to the area covered by the catalytic material, the HF molecule (a) also makes a nucleophilic attack on the Si atom (b) as expressed by Formula (i).

However, in this case, in addition to this attack, the O atom of the −δ part (e) of the polar functional group interacts with H of the HF molecule (a). Further, the H atom of the +δ part (f) of the polar functional group interacts with the OH group (c) present on the surface.

Therefore, as expressed by Formula (ii), the H—F bond of the HF molecule (a) is weakened. Further, the bond between Si (b) and OH (c) is also weakened. As a result, the activation energy required for the bonding reaction between the Si atom and the F atom is lowered.

As a result, as expressed by Formula (iii), the H atom of the HF molecule (a) is taken away by the O atom of the −δ part (e) of the polar functional group, and the H atom of the +δ part (f) reacts with the OH group present on the surface, so that H₂O (g) is eliminated.

As a result, the Si atom (b) is bonded to the fluorine atom. Eventually, SiF₄ and H₂O are formed as expressed by the below-shown Reaction Formula (1).

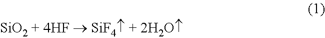

Both SiF₄ and H₂O generated by the reaction are gases at the processing temperature and are rapidly dispersed to the outside of the system.

By the above-described reaction mechanism, the part of the object to be processed located directly below the area covered by the catalytic material is selectively etched.

Note that the above-described reaction is not limited to those in the case where the polar functional group contains a hydroxy group. For example, a similar reaction can occur when the polar functional group contains at least one of an aldehyde group, a hydroxy group, a carboxy group, an amino group, a sulfo group, a thiol group, and an amide bond.

Further, in FIG. 2, the reaction mechanism has been described by using an example case where the polar functional group of the organic compound contains an H atom. However, the polar functional group of the organic compound is not limited to those containing an H atom.

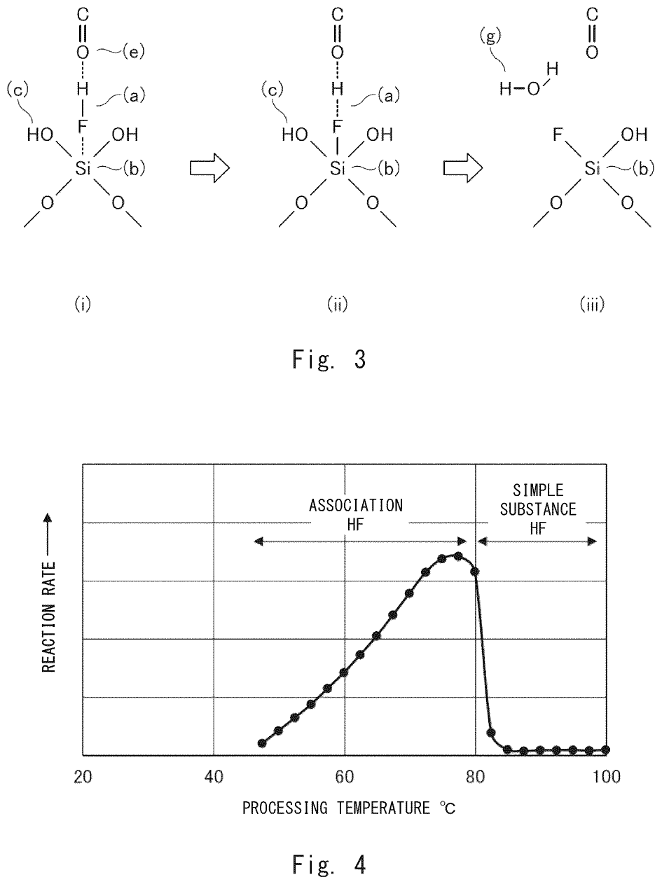

FIG. 3 schematically shows a reaction mechanism when the organic compound contains another type of polar functional group. In this example, it is assumed that the polar functional group is a carbonyl group having no H atom (>C=O).

Even in this example, when an HF gas is supplied from the environment to the area covered by the catalytic material, the HF molecule (a) also makes a nucleophilic attack on the Si atom (b) as expressed by Formula (i). Further, the O atom of the −δ part (e) of the polar functional group interacts with the H atom of the HF molecule (a).

As a result, as expressed by Formula (ii), the H—F bond of the HF molecule (a) is weakened.

Next, as expressed by Formula (iii), the H atom separated from the HF molecule (a) by the O atom of the −δ part (e) of the polar functional group binds with the OH group (c), so that H₂O (g) is generated.

As described above, even in this case, the activation energy required for the bonding reaction between the Si atom and the F atom is lowered. As a result, the reaction expressed by the above-described Reaction Formula (1) occurs, and hence the part of the object to be processed located directly below the covered area is selectively etched.

A similar reaction mechanism can occur when the polar functional group has, for example, at least one of a carbonyl group, a nitro group, a cyano group, an ether bond, and an ester bond.

As described above, in the basic etching technique, because of the presence of the organic compound containing the polar functional group, contained in the catalytic material, the fluoride generation reaction is expedited in the covered area on the object to be processed, so that the part directly below the covered area can be selectively etched.

### (Effect of Processing Temperature)

Next, the effect of the processing temperature will be described.

In the basic etching technique, the processing temperature is 80° C. or higher. This is because when the temperature is lower than 80° C., proper etching selectivity is not obtained between the covered area and the uncovered area on the first surface of the object to be processed.

The effect of the processing temperature will be described hereinafter in detail with reference to FIG. 4.

FIG. 4 shows a relationship between the processing temperature and the etching reaction rate when hydrogen fluoride (HF) gas etching is performed on glass, acquired by the inventors of the present application.

From FIG. 4, when the processing temperature is lower than 80° C., the etching rate in the glass gradually increases as the temperature rises. However, when the processing temperature rises to 80° C. or higher, the etching rate sharply decreases. As a result, the etching rate has a peak at a temperature lower than 80° C.

It is presumed that this phenomenon corresponds to the association/non-association state of the HF gas. That is, while the HF gas is in the association state when the processing temperature is lower than 80° C., it is in the non-association state (simple substance) when the processing temperature is equal to or higher than 80° C. Further, when attention is paid to one molecule, when the HF gas is in the association state, the binding force of the H—F bond is relatively weak. Therefore, the F atom of the HF molecule easily binds with the surface of the object to be processed, and thereby easily forms a fluoride. It is presumed that because of such behavior, a high etching rate can be easily obtained at a temperature lower than 80° C.

In the basic etching technique, if the processing temperature is set to a temperature lower than 80° C., the association state of the HF gas is affected, so that the area not covered by the catalytic material on the object to be processed is etched. Therefore, the etching selectivity in the covered area by the above-described reaction mechanism deteriorates.

In contrast, when the processing temperature is set to 80° C. or higher, the high etching force caused by the HF gas which is in the association state can be suppressed in the area not covered by the catalytic material. Further, based on the above-described reaction mechanism, etching can be performed on the part directly below the covered area on the object to be processed. As a result, high etching selectivity can be obtained between the area covered by the catalytic material and the area not covered by the catalytic material at the processing temperature equal to or higher than 80° C. Further, because of this high etching selectivity, the covered area can be selectively etched in the basic etching technique.

### (Recessed Structure to be Formed)

In the basic etching technique, a recess structure including a sidewall(s) extending substantially parallel to the perpendicular line of the surface of the object to be processed (hereinafter referred to as a “vertical recess structure”) can be formed relatively easily.

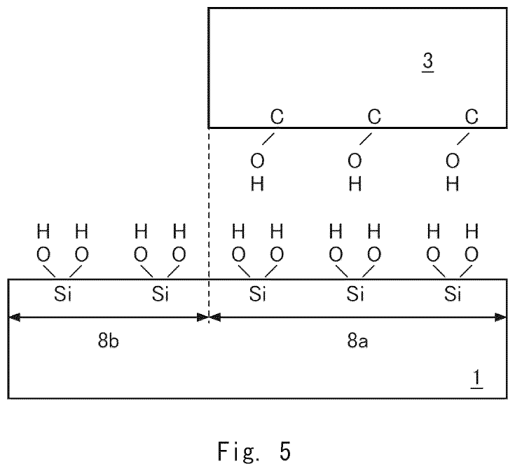

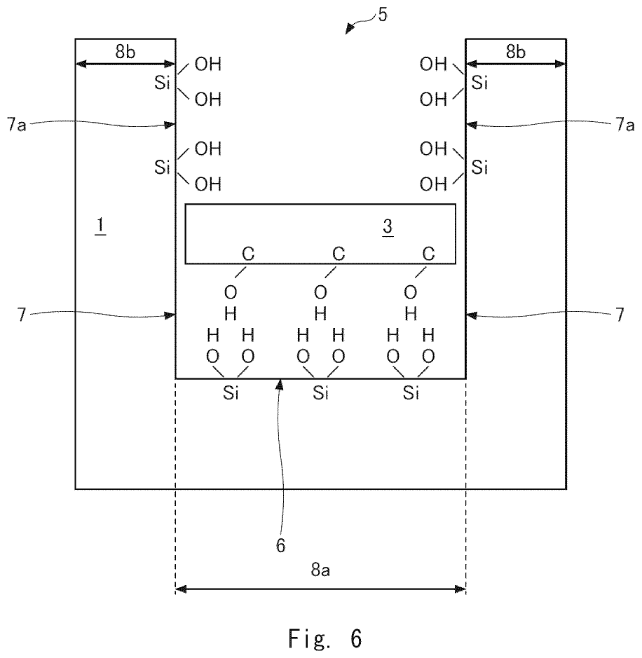

The reason for this feature will be described hereinafter with reference to FIGS. 5 and 6.

Each of FIGS. 5 and 6 schematically shows one process in the basic etching technique.

FIG. 5 schematically shows a state where a catalytic material 3 is placed on a surface of an object to be processed 1. Note that the object to be processed 1 and the catalytic material 3 are shown as if they are separated from each other in FIGS. 5 and 6 for the sake of visual explanation, in reality, they are in contact with each other.

As described above, it is assumed that the object to be processed 1 is made of SiO₂, and the surface is H-terminated.

The catalytic material 3 is an organic compound containing a polar functional group. Further, in this example, it is assumed that the polar functional group is an OH group. A covered area 8a and an uncovered area 8b are formed on the object to be processed 1 by placing the catalytic material 3 on the surface of the object to be processed 1.

As described above, etching selectively proceeds directly below the covered area 8a, where the catalytic material 3 is placed, by exposing the object to be processed 1, which is heated to 80° C. or higher, to an HF gas. As a result, a recess structure is formed directly below the covered area 8a.

FIG. 6 shows a state where the etching of the object to be processed 1 has proceeded to some extent and a recess structure 5 having a certain depth has been formed.

As described above, the catalytic material 3 is placed in the covered area 8a. Therefore, even when the etching reaction has proceeded, the catalytic material 3 still exists on the bottom surface 6 of the recess structure 5. That is, while the etching process is continued, the bottom surface 6 of the recess structure 5 is continuously in contact with the catalytic material 3. Therefore, the bottom surface 6 of the recess structure 5 is continuously etched by the reaction mechanism described above, and the bottom surface 6 continuously proceeds in the depth direction.

Meanwhile, when attention is paid to the sidewall 7 of the recess structure 5, once the etching is started, the etching reaction proceeds in the part of the sidewall 7 that is in contact with the catalytic material 3 according to the mechanism described above. More precisely, only the part that is in contact with the side surface of the catalytic material 3 of the object to be processed 1 is etched. As a result, the recess structure 5 defined by the sidewall 7 is formed in the place that is in contact with the side surface of the catalytic material 3.

However, since the catalytic material 3 is continuously lowered deeper and deeper, the upper part of the sidewall 7 is no longer in contact with the side surface of the catalytic material 3 at and after a certain time point. In the following description, the part of the sidewall 7 that is no longer in contact with the side surface of the catalytic material 3 is referred to as a “first sidewall part 7a”.

Note that as described above, etching substantially does not proceed in the place where the catalytic material 3 no longer exists, such as in the uncovered area 8b. In other words, in the object to be processed 1, the etching reaction occurs only when it is in contact with the catalytic material 3, and does not occur in the other states. Therefore, in the sidewall 7, in the place that is no longer in contact with the catalytic material 3, such as in the first sidewall part 7a, the etching process substantially stops thereafter.

In the basic etching technique, as a result of the etching stopping action at the first sidewall part 7a, which is no longer in contact with the catalytic material 3 as described above, the etching of the object to be processed 1 selectively proceeds only in the part directly below the catalytic material 3, so that a vertical recess structure can be eventually formed.

That is, in the basic etching technique, a recess structure 5 in which the area (i.e., the size) of the opening is substantially equal to the area (i.e., the size) of the bottom surface is formed.

Further, the basic etching technique includes a step of irradiating the catalytic material with irradiation light containing deep ultraviolet light (DUV) having a wavelength of 380 nm or shorter (hereinafter referred to as a “DUV irradiation process”) before performing the etching process on the object to be processed. When such a DUV irradiation process is added, the etching rate of the object to be processed can be controlled in the subsequent etching process.

Note that it is presumed that in the basic etching technique, the etching rate of the object to be processed can be controlled by performing the etching process after performing the DUV irradiation process because the number of polar functional groups changes by the DUV irradiation process.

This phenomenon will be described hereinafter by referring to FIG. 5 again.

As shown in FIG. 5, when the catalytic material 3 is placed on the surface of the object to be processed 1, a covered area 8a and an uncovered area 8b are formed on the object to be processed 1.

Because of the presence of the catalytic material 3, the reaction barrier in Reaction Formula (1) is lowered in the covered area 8a as described above, so that the etching selectively proceeds in the covered area 8a during the etching process.

However, when the DUV irradiation process is performed, a crosslinking reaction occurs in the catalytic material 3 as a result of exposure to the deep ultraviolet light having a wavelength of 380 nm or shorter. By the crosslinking reaction, the number of polar functional groups (e.g., C—OH groups) contained in the catalytic material 3 decreases. Therefore, it is presumed that during the subsequent etching process, the effect for reducing the reaction barrier in the above-described Reaction Formula (1) is weakened, and hence the etching rate decreases.

Further, in this case, the number of polar functional groups contained in the catalytic material 3 is also changed by changing the irradiation intensity of the irradiation light containing deep ultraviolet light and the irradiation time of the irradiation light in the DUV irradiation process. Therefore, in the etching process, the etching rate of the object to be processed 1 can be controlled by changing the irradiation conditions in the DUV irradiation process.

For example, in the case where a relatively shallow recess structure is formed, the irradiation intensity of the irradiation light may be increased and/or the irradiation time may be increased in the DUV irradiation process. As a result, the etching rate in the etching process can be meaningfully lowered, so that over-etching for the object to be processed can be prevented.

Further, in the case where a relatively deep recess structure is formed, the irradiation intensity of the irradiation light may be lowered and/or the irradiation time may be shortened in the DUV irradiation process. As a result, the etching rate in the etching process can be increased, so that the fabrication time can be shortened.

As described above, in the basic etching technique, a member with a vertical recess structure can be manufactured at various etching rates.

### (New Microfabrication Technique Developed by Inventor of Present Application)

A new microfabrication technique developed by the inventors of the present application is based on the above-described “basic etching technique”.

That is, according to an embodiment of the present invention,
a method for manufacturing a member with a recess structure comprises:
(1) a step of placing a catalytic material in a first area on a first surface of an object to be processed, in which
the first surface is made of an element of which a boiling point of a fluoride is 550° C. or lower,
the catalytic material contains an organic compound containing a polar functional group, and
the catalytic material includes, in a cross-sectional view of the catalytic material, i.e., in cross section perpendicular to the first surface, a first side surface having a first height H1 and a second side surface having a second height H2, the first and second side surfaces being opposed to each other, in which H1>0 μm, H2>0 μm, and the height H1 is higher than the height H2:
(2) a step of irradiating the catalytic material with irradiation light containing deep ultraviolet light having a wavelength of 380 nm or shorter; and
(3) a step of exposing the object to be processed to a fluorine-containing gas at 80° C. or higher, wherein
a recess structure is formed below the first area after the step (3), and the recess structure has, in the cross-sectional view, at a center of the first area, a shape inclined toward the second side surface from a perpendicular line dropped from the first surface.

Note that the shape inclined toward the second side surface of the recess structure may be a straight shape or a curved shape.

An embodiment according to the present invention has a such a feature that in the cross-sectional view of the catalytic material, the catalytic material placed on the first surface has a first side surface and a second side surface opposed to each other, and the height H1 of the first side surface is higher than the height H2 (H2≥0 μm) of the second side surface.

Note that the “cross-sectional view (of the catalytic material)” means that the target member (e.g., the catalytic material) is viewed in cross section perpendicular to the first surface of the object to be processed.

Further, the first side surface of the catalytic material has a height H1 having a certain positive value, but the height H2 of the second side surface may be zero. That is, in the present application, while the height H1 is expressed as H1>0 μm, the height H2 is expressed as H1>0 μm. Note that in the case where H2=0, the catalytic material may have, for example, a roughly triangular cross section.

When the above-described DUV irradiation process and the etching process are performed after a catalytic material having such a form is placed, a recess structure having a shape inclined toward the second side surface can be formed in the object to be processed.

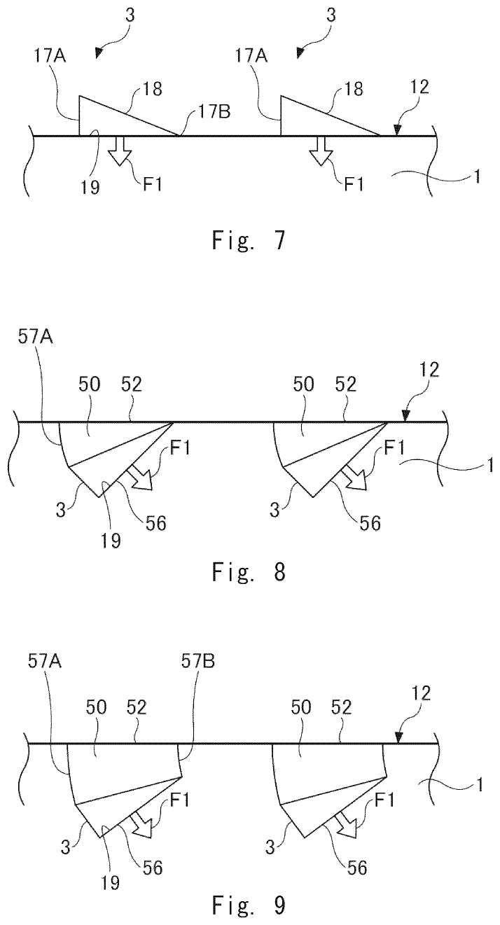

This mechanism will be described hereinafter with reference to FIGS. 7 to 9.

FIGS. 7 to 9 schematically show a process through which a recess structure is formed in a first surface of an object to be processed in an embodiment according to the present invention.

FIG. 7 shows a state in which a pattern of a catalytic material 3 is set on a first surface 12 of an object to be processed 1. FIG. 8 shows a state after an etching process is started for the object to be processed 1, which has already been subjected to the DUV irradiation process, (at an etching time t1). Further, FIG. 9 shows a state in which the etching process for the object to be processed 1 has further proceeded (at an etching time t2, t2>t1). t2>t1.

In the example shown in FIG. 7, in the cross-sectional view, pieces of the catalytic material 3 each having a triangular shape are placed on the first surface 12. The catalytic material 3 (i.e., each piece of the catalytic material 3) has a top surface 18 and a bottom surface 19. The height of the top surface 18 continuously lowers from the maximum value on the left side in FIG. 7 to the minimum value (zero) on the right side.

Note that it can be said that the catalytic material 3 shown in FIG. 7 has a first side surface 17A having a height H1 on the first side (left side in FIG. 7) and a second side surface 17B having a height H2 on the second side (right side in FIG. 7). However, H2 is zero (H2=0) in the example. That is, while H1 is larger than zero (H1>0), H2 is equal to or larger than zero (H2≥0) in the present application.

In such a state, when an etching process is performed on the object to be processed 1, of which the DUV irradiation process has already been performed on the catalytic material 3, the first surface 12 is etched by the catalytic material 3 in a direction indicated by the arrow F1.

Note that as shown in FIG. 7, when the heights of the catalytic material 3 are set as H1>H2, there is a difference between the amount of polar functional groups contained on the first side surface 17A side in the catalytic material 3 and that of polar functional groups contained on the second side surface 17B side. Therefore, the etching rate of the object to be processed 1 varies between both sides. That is, the etching rate on the first side surface 17A side, on which the amount of polar functional groups is large, is higher than that on the second side surface 17B side.

As a result, as shown in FIG. 8, when the etching process proceeds, the formed recess structure 50 becomes deeper directly below the first side surface 17A of the catalytic material 3 than directly below the second side surface 17B thereof.

When the etching process is further continued, the difference between the etching rate at the first side surface 17A and that at the second side surface 17B becomes more noticeable. Therefore, as shown in FIG. 9, in the formed recess structure 50, the sidewall 57A corresponding to the first side surface 17A of the catalytic material 3 becomes longer than the sidewall 57B corresponding to the second side surface 17B. As a result, the recess structure 50 has such a shape that it is inclined toward the second side surface 17B. For example, in the example shown in FIG. 9, the recess structure 50 has a non-straight shape in which it is curved toward the second side surface 17B.

As a result, in an embodiment according to the present invention, it is possible to manufacture a member with a recess structure 5 inclined in a predetermined direction below its first surface 12.

Note that in an embodiment according to the present invention, as shown in FIG. 9, because of the above-described mechanism, the area (i.e., the size) of the bottom surface 56 of the recess structure 50 and that of the opening 52 thereof are substantially equal to each other at any stage of the etching process. That is, in an embodiment according to the present invention, the formed recess structure 50 has such a feature that in the cross-sectional view, the width is substantially constant in the extending direction.

(Method for Manufacturing Member with Recess Structure According to Embodiment of Present Invention)

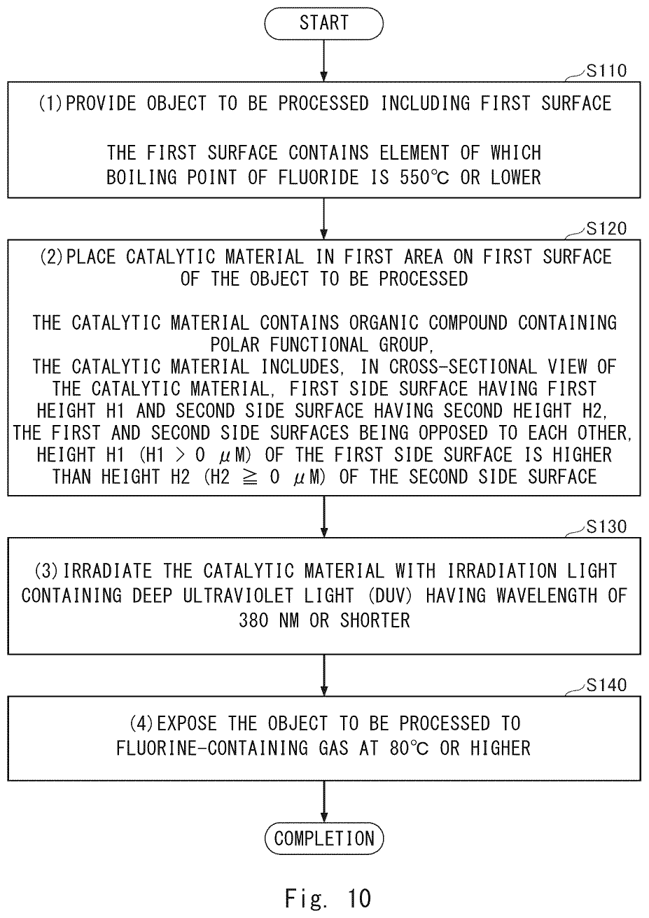

Next, a method for manufacturing a member with a recess structure according to an embodiment of the present invention will be described in a more detailed manner with reference to FIGS. 10 to 12.

FIG. 10 schematically shows a flow of a method for manufacturing a member with a recess structure according to an embodiment of the present invention (hereinafter also referred to simply as the “first method”).

As shown in FIG. 10, the first method comprises:
(1) a step (S110) of preparing an object to be processed including a first surface, in which the first surface contains an element of which a boiling point of a fluoride is 550° C. or lower;
(2) a step (S120) of placing a catalytic material in a first area on a first surface of the object to be processed, in which
the catalytic material contains an organic compound containing a polar functional group,
the catalytic material includes, in a cross-sectional view of the catalytic material, a first side surface having a first height H1 and a second side surface having a second height H2, the first and second side surfaces being opposed to each other, and
the height H1 (H1>0 μm) of the first side surface is higher than the height H2 (H2>0 μm) of the second side surface:
(3) a step (S130) of irradiating the catalytic material with irradiation light containing deep ultraviolet light (DUV) having a wavelength of 380 nm or shorter; and
(4) a step (S140) of exposing the object to be processed to a fluorine-containing gas at 80° C. or higher.

Each of the steps will be described hereinafter.

### (Step S110)

Firstly, an object to be processed is prepared.

The object to be processed may be formed of one member or a plurality of members.

When the object to be processed is formed of one member, the object to be processed is formed of an element of which a fluoride having a boiling point of 550° C. or lower is formed by a reaction with fluorine (F).

For example, the object to be processed may contain at least one element selected from the group consisting of B, C, Si, P, S, Ti, V, Cr, Ge, As, Se, Nb, Mo, Tc, Ru, Rh, Sn, Sb, Te, I, Ta, W, Re, Os, Ir, Pt, and Au. Further, the object to be processed may also contain at least one element selected from the group consisting of H, N, Cl, Br, and O.

In particular, the object to be processed is preferably formed of an element of which a fluoride having a boiling point of 200° C. or lower is formed by a reaction with fluorine.

For example, regarding silicon (Si), its fluoride SiF₄ has a boiling point of −86° C., so that an object to be processed containing silicon can be suitably used as the object to be processed in the first method.

Note that regarding Al and Ca, the boiling points of their fluoride (AlF₃) and (CaF₂) both exceed 550° C. Therefore, Al and Ca cannot be regarded as elements of which a fluoride having a boiling point of 550° C. or lower is formed by a reaction with fluorine (F).

The object to be processed may be, for example, a quartz glass substrate, a crystal substrate, or a silicon substrate.

Meanwhile, when the object to be processed is formed of a laminate of a plurality of members, the object to be processed contains an element of which the boiling point of the fluoride is 550° C. or lower on the outermost surface (corresponding to the “first surface” in the present application) thereof.

As described above, such an element may be selected from, for example, the group consisting of B, C, Si, P, S, Ti, V, Cr, Ge, As, Se, Nb, Mo, Tc, Ru, Rh, Sn, Sb, Te, I, Ta, W, Re, Os, Ir, Pt, and Au. Further, the first surface may contain at least one element selected from the group consisting of H, N, Cl, Br, and O.

For example, the object to be processed may include one or two or more films placed on the substrate, and the outermost surface film may have the above-described features. Alternatively, all of the plurality of films may have the above-described features. Such a film may contain, for example, at least one of SiO₂, Si₃N₄, and SiC.

Alternatively, the substrate as well as the film may have the above-described features. In this case, a member with a recess structure which is formed deeply inside the substrate can be manufactured by the first method. The substrate may be, for example, a quartz glass substrate, a crystal substrate, or a silicon substrate.

Note that in the following description, in order to prevent the explanation from becoming complicated, it is assumed that the object to be processed is formed of one quartz glass, and a recess structure is formed on a first surface of this quartz glass.

### (Step S120)

Next, a catalytic material is placed on the first surface of the object to be processed. The catalytic material is placed in a predetermined area on the first surface.

The catalytic material includes an organic compound containing a polar functional group. The polar functional group may contain, for example, at least one group or bond selected from the group consisting of a hydroxy group, an aldehyde group, a carboxy group, an amino group, a sulfo group, a thiol group, an amide bond, a carbonyl group, a nitro group, a cyano group, an ether bond, and an ester bond.

Typical examples of such organic compounds include phenolic resins, acrylic resins, and methacrylic resins.

The catalytic material may be formed of only the organic compound containing a polar functional group described above, or may be provided as a mixture with other additives.

In the latter case, the catalytic material may contain a solvent, a binder, and/or fine particles.

The method for placing a catalytic material is not limited to any particular methods.

The catalytic material may be placed on the first surface of the object to be processed by using, for example, a coating method, a printing method, a spin coating method, or a spray method.

FIG. 11 schematically shows a state in which the catalytic material is placed on the object to be processed.

As shown in FIG. 11, the object to be processed 110 includes a first surface 112 and a second surface 114. Catalytic materials 130 (i.e., pieces of catalytic material 130) are placed on parts of the first surface 112 of the object to be processed 110.

Note that in the example shown in FIG. 11, pieces of the catalytic material 130 (hereinafter also referred to simply as catalytic materials 130) are placed in the form of a pattern 131 consisting of a plurality of parallel lines. However, this pattern is merely an example, and the catalytic materials 130 may be placed in any form according to the required recess structure. The catalytic materials 130 may be disposed, for example, in the form of one straight line. Alternatively, the catalytic materials 130 may be arranged, for example, as a pattern consisting circular dots or may be disposed as one circular dot.

Note that according to the above-described definition, on the first surface 112, the areas where the catalytic materials 130 are placed are referred to as a covered area(s) 140a, and the remaining area(s) is referred to as an uncovered area(s) 140b.

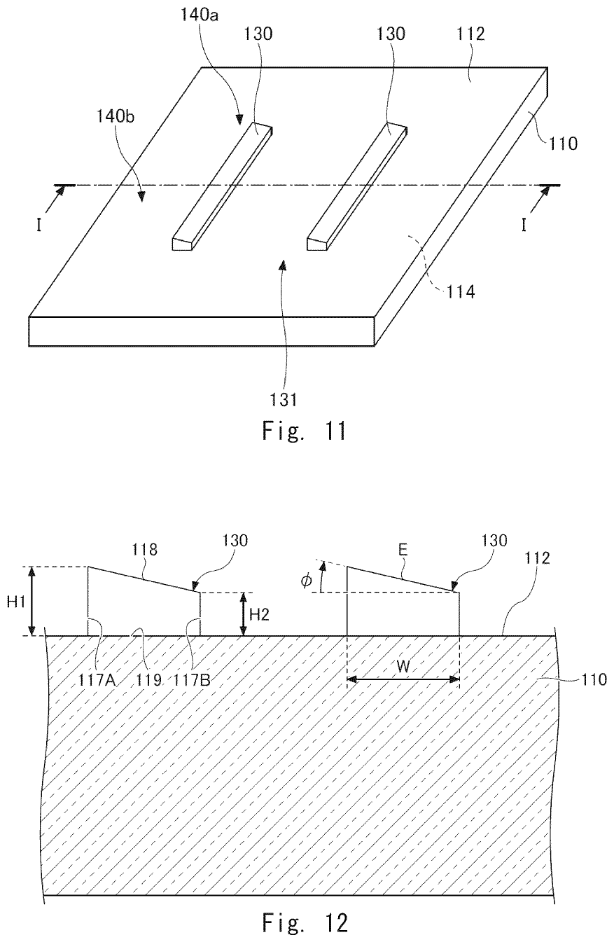

FIG. 12 schematically shows a part of the cross section cut along a line I-I shown in FIG. 11.

As shown in FIG. 12, each catalytic material 130 (i.e., each piece of the catalytic material 130) has such a shape that in the cross-sectional view, the thickness (height) varies between the left and right sides.

That is, each catalytic material 130 has a top surface 118, a bottom surface 119, and has a first side surface 117A and a second side surface 117B having different heights. Further, the height H1 of the first side surface 117A is higher than the height H2 of the second side surface 117B. Therefore, the top surface 118 of the catalytic material 130 (i.e., each piece of the catalytic material 130) has an inclined surface in which the second side surface 117B side is lowered.

However, the shape of the catalytic material 130 is not limited to any particular shapes as long as the height H1 is higher than the height H2 (H1>H2). The catalytic material 130 may have, in the cross-sectional view, any of various shapes such as a shape obtained by rotating a trapezoid by 90° as shown in FIG. 12 as well as a triangle as shown in FIG. 7 described above.

Further, in the cross-sectional view, the top surface 118 of the catalytic material 130 does not necessarily need to be a straight shape connecting the tops of the first and second side surfaces 117A and 117B. For example, in the cross-sectional view, the top surface 118 of the catalytic material 130 may be a non-straight shape such as a downward-projecting curved shape or an upward-projecting curved shape. Alternatively, the top surface 118 may have one or more level-differences (steps).

Note that in the catalytic material 130, in the cross-sectional view, an angle φ (0°<φ<90°) formed between a straight line E connecting the first and second side surfaces 117A and 117B and the first surface 112 (which coincides with the top surface 118 in the example shown in FIG. 12) may be within a range of 1° to 80°.

φ is preferably within a range of 3° to 50°, and more preferably within a range of 5° to 15°.

Further, the width W of the catalytic material 130 (see FIG. 12) is not limited to any particular values, but may be in a range of, for example, 0.1 μm to 100 μm, and is preferably in a range of 0.3 μm to 50 μm.

### (Step S130)

Next, the catalytic materials 130 are irradiated with irradiation light. The irradiation light contains deep ultraviolet light (DUV) having a wavelength of 380 nm or shorter. The wavelength of the deep ultraviolet light may be in a range of 200 nm to 365 nm.

In a typical case, the irradiation light is emitted from a light source. Such a light source may be a light source that emits light having one wavelength (or one wavelength range) or a light source that emits light having a plurality of wavelengths (or a plurality of wavelength ranges).

The irradiation conditions such as the irradiation intensity and irradiation time of the irradiation light are determined based on the etching rate that will be adopted in a step S140 performed later. That is, as the irradiation intensity of the irradiation light is increased and the irradiation time thereof is increased, the maximum etching rate of the object to be processed in the step S140 decreases.

It should be noted that the degree of inclination of the recess structure formed after the step S140 is determined by the difference between the etching rates caused by the difference between the amounts of polar functional groups contained in both side surfaces (on the side surface 17A side and the second side surface 17B side) of the catalytic material. Therefore, even when the intensity of the DUV irradiation applied to the entire surface of the catalytic material is changed, the degree of inclination of the recess structure itself does not significantly change.

For example, the irradiation amount P (mJ/cm²) of the irradiation light may be 20 mJ/cm² or larger.

Note that the irradiation amount P of the irradiation light is expressed by the below-shown Expression (2):

$$Irradiation amount P ( mJ / {cm}^{2} ) = Irradiation intensity of Lamp A ( mW / {cm}^{2} ) \times Irradiation time ( sec ) \qquad ( 2 )$$

### (Step S140)

Next, the object to be processed 110, in which the catalytic materials 130 have been placed, is put in a processing chamber. After that, for the etching process of the object to be processed, the inside of the processing chamber is heated to a predetermined temperature, and a processing gas is supplied thereto.

The processing gas includes a hydrogen fluoride gas or a fluorine gas. For example, the concentration of the processing gas may be adjusted to a predetermined concentration by using a carrier gas such as an argon gas or a nitrogen gas. In this case, the concentration of the hydrogen fluoride gas or fluorine gas may be, for example, in a range of 0.1 vol % to 100 vol %.

As described above, the processing temperature is 80° C. or higher. The actual processing temperature changes depending on the elements contained in the object to be processed 110 (in particular, the first surface 112), and the type, the depth, and the like of the recess structure. However, in a typical case, the processing temperature is in a range of 200° C. to 450° C., and preferably in a range of 250° C. to 400° C. By setting the processing temperature to 450° C. or lower, the degradation of the organic compound contained in the catalytic materials 130 can be suppressed.

As described above, the above-described Reaction Formula (1) occurs in the covered area 140a by performing the etching process on the object to be processed 110 under the above-described environment. Further, the fluoride and water generated by the reaction become gases and are dispersed to the outside of the system. As a result, a recess structure inclined in a predetermined direction is formed in the covered area 140a of the first surface 112.

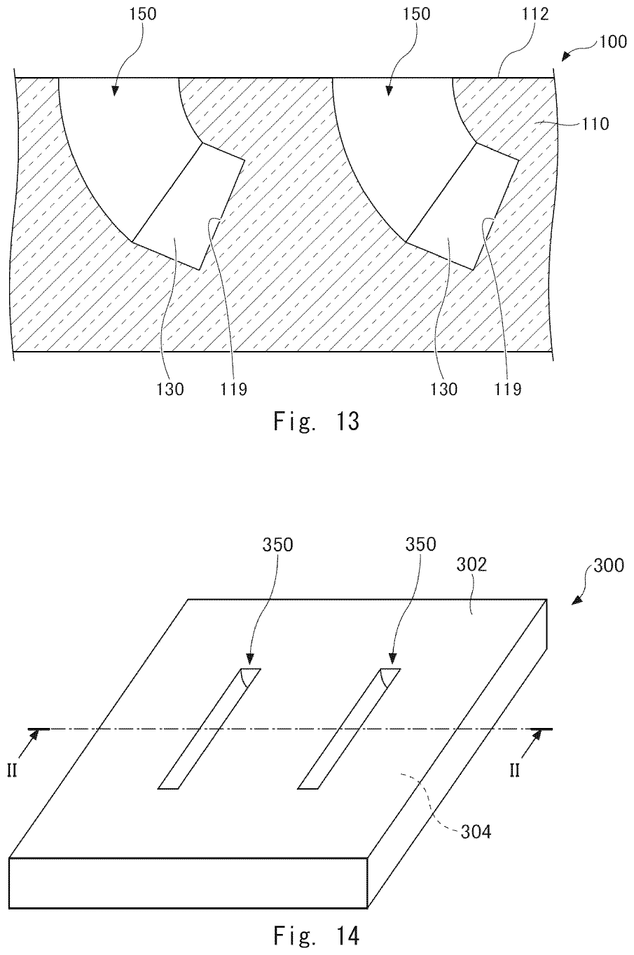

FIG. 13 schematically shows an example of a cross section of the object to be processed 110 after the etching process.

As shown in FIG. 13, in the first method, a curved recess structure 150 inclined toward the right may be formed after the step S140.

After that, a step of removing the catalytic material 130 remaining on the bottom surfaces of the recess structure 150 may be performed. For example, the catalytic materials 130 may be removed by cleaning the object to be processed 110 with an acid solution, an alkali solution, an organic solvent, a corrosive gas, or plasma.

Through the above-described steps, the member 100 with the recess structure 150 inclined in a predetermined direction can be manufactured in the first surface 112.

The depth of the recess structure 150 is, for example, 10 μm or deeper or may be 15 μm or deeper.

(Member with Recess Structure According to an Embodiment of Present Invention)

Next, a member with a recess structure according to an embodiment of the present invention will be described with reference to FIGS. 14 to 16.

FIG. 14 is a perspective view of a member with recess structures according to an embodiment of the present invention (hereinafter referred to as a “first member 300”). Further, FIG. 15 shows a schematic enlarged cross-sectional diagram of the first member 300 shown in FIG. 14 taken along a line II-II shown therein.

As shown in FIG. 14, the first member 300 includes a first surface 302 and a second surface 304 which face each other. Further, the first member 300 includes recess structures 350 on the side thereof on which the first surface 302 is located.

Note that in the example shown in FIG. 14, the first and second surfaces 302 and 304 of the first member 300 have substantially rectangular shapes. However, the shapes of the first and second surfaces 302 and 304 are not limited to any particular shapes.

Further, in the example shown in FIG. 14, two recess structures 350 are formed in the first surface 302, and these two recess structures 350 are arranged parallel to each other. Further, each recess structure 350 has a straight opening extending in one direction.

However, this is merely an example, and the number, shape, and arrangement of the recess structures 350 are not limited to any particular numbers, shapes, and arrangements.

As shown in FIG. 15, the recess structures 350 include openings 352 on the first surface 302. Further, the recess structures 350 also include bottom surfaces 356 and sidewalls 357.

In other words, the recess structure 350, i.e., each of the recess structures 350, is defined by the opening 352, the bottom surface 356, and the sidewall 357.

In the first member 300, the recess structure 350 (i.e., each of the recess structures 350) has a shape inclined in a predetermined direction. Specifically, in the recess structure 350, the sidewall 357 does not extend parallel to the vertical direction, but is inclined toward the right. Further, the sidewall 357 of the recess structure 350 have a curved shape.

However, the recess structure 350 has such a feature that the size P1 of the opening 352 (which may be regarded as the area of the opening 352) and the size P2 of the bottom surface 356 (which may be regarded as the area of the bottom surface 356) are substantially equal to each other as viewed in cross section perpendicular to the first surface 302 (i.e., in the cross-sectional view).

Specifically, a ratio P2/P1 is equal to or higher than 0.90, and lower than 1.1. In particular, the ratio P2/P1 is preferably in a range of 0.94 to 1.05.

The first member 300 described above can be manufactured by, for example, the first method described above.

In the first member 300, the recess structure 350 may have a depth of 10 μm or deeper.

Further, as shown in FIG. 15, the recess structure 350 may have such a form that an angle α (0°<α<180°) of the sidewall 357 with respect to a plane parallel to the first surface 302 continuously changes from the opening 352 to the bottom surface 356. Note that the angle α means an angle between the tangent of the sidewall 357, which passes the “outside” of the recess structure 350, and the horizontal plane. Further, as shown in FIG. 15, in particular, the angle α of the sidewall 357 measured at the intersection of the sidewall 357 and the bottom surface 356 is represented by “ab”.

The angle α_{b} may have any value, but may be, for example, in a range of 10° to 80°.

In particular, as shown in FIG. 21 (which will be described later), the recess structure 350 may have such a curved shape that the center of the opening 352 and the center of the bottom surface 356 cannot be connected by a straight line in the cross-sectional view.

Further, the first member 300 has such a feature that a surface constituting the sidewall 357 in the recess structure 350 is relatively smooth and has a surface roughness Ra of 5 nm or finer. In particular, the surface roughness Ra of the sidewalls 357 are preferably 4.5 nm or finer, and more preferably 4.0 nm or finer.

These features will be described hereinafter.

As described above with reference to FIGS. 5 and 6, in the first method based on the basic etching technique, the covered area 8a is selectively etched owing to the catalytic material 3 placed on the covered area 8a. Further, as long as the relationship between the catalytic material 3 and the covered area 8a is maintained, the recess structure 5 continuously proceeds in the depth direction.

In the case of such an etching mechanism, the sidewall 7 of the recess structure 5 generated by the etching is affected by the state of the side surface of the catalytic material 3 with which the sidewall 7 is in contact.

In general, it is considered that the side surface of the catalytic material 3 is relatively smooth with few irregularities. Because of the effect of such few irregularities on the side surface of the catalytic material 3, the sidewall 7 of the recess structure 5 has a relatively smooth surface. As a result, it is expected that the sidewall 7 of the recess structure 5 has a surface of which the surface roughness is meaningfully suppressed.

Such smoothness is not observed in members subjected to etching processes in the related art and hence is meaningful. For example, in ordinary RIE methods, the sidewall of the recess is affected by the collisions of ions during the fabrication, and hence may have relatively large irregularities thereon.

Further, the first member 300 can have a feature that the sidewall 357 has a streak pattern extending along the extending direction of the recess structure 350.

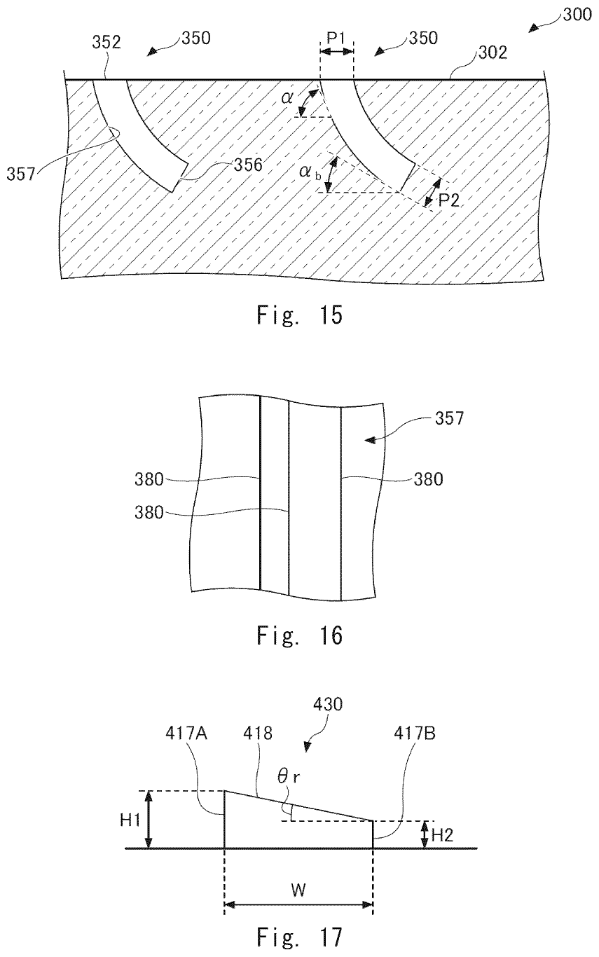

This feature will be described hereinafter with reference to FIG. 16.

FIG. 16 schematically shows a form of the surface of the sidewall 357 of the recess structure 350. FIG. 16 schematically shows a part of the surface of the sidewall 357.

As shown in FIG. 16, in the first member 300, in the sidewall 357 of the recess structure 350, continuous streaks (hereinafter referred to as “continuous streaks”) 380 extending from the opening 352 to the bottom surface 356 are formed.

Note that in FIG. 16, three continuous streaks 380 are shown. However, this is merely an example, and the number of streaks 380 is not limited to any particular numbers.

It is presumed that such a pattern of streaks 380 is also formed by the above-described mechanism.

That is, as shown in FIG. 6, the sidewall 7 of the recess structure 5 generated by the etching in the basic etching technique is affected by the state of the side surface of the catalytic material 3 with which the sidewall 7 is in contact.

Further, in the first method, the catalytic material 3 having such irregularities on the side surface proceeds to the bottom surface 6 of the recess structure 5 in the depth direction of the recess structure 5. Therefore, a pattern of streaks corresponding to such irregularities is likely to be also formed on the sidewall 7 of the eventually obtained recess structure 5.

It is presumed that, as a result, continuous streaks 380 extending in the depth direction are formed on the sidewall 357.

### (Other Features of First Member 300)

The first member 300 may be a single member, or may be formed of a plurality of members.

When the first member 300 is formed of one member, the first member 300 is formed of an element of which a fluoride having a boiling point of 550° C. or lower is formed by a reaction with fluorine (F).

For example, the first member 300 may contain at least one element selected from the group consisting of B, C, Si, P, S, Ti, V, Cr, Ge, As, Se, Nb, Mo, Tc, Ru, Rh, Sn, Sb, Te, I, Ta, W, Re, Os, Ir, Pt, and Au. Further, the object to be processed may also contain at least one element selected from the group consisting of H, N, Cl, Br, and O.

When the first member 300 is formed of one member, the first member 300 may be, for example, a quartz glass substrate or a crystal substrate.

Meanwhile, when the first member 300 is formed of a plurality of members, the first member 300 contains, on the first surface 302, an element of which a boiling point of a fluoride is 550° C. or lower.

As described above, such an element may be selected from, for example, the group consisting of B, C, Si, P, S, Ti, V, Cr, Ge, As, Se, Nb, Mo, Tc, Ru, Rh, Sn, Sb, Te, I, Ta, W, Re, Os, Ir, Pt, and Au. Further, the first surface 302 may also include at least one element selected from the group consisting of H, N, CI, Br, and O.

For example, the first member 300 may have one or two or more films placed on the substrate material, and the outermost surface film may have the above-described features. Alternatively, all of the plurality of films may have the above-described features.

Such a film may contain, for example, at least one of SiO₂, Si₃N₄, and SiC. Alternatively, the substrate material as well as the film may have the above-described features.

The first member 300 having such features can be applied to, for example, various applications such as MEMS devices, micro-hydraulic devices, semiconductor devices, optical devices, meta-surface devices, molds for resin molding, window glasses, and cover glasses.

### EXAMPLES

Examples according to the present invention will be described hereinafter. Note that in the following description, Examples 1 to 4 are examples according to the present invention.

### Example 1

Recessed structures were formed on one of the surfaces (first surface) of an object to be processed by a method described hereinafter.

Firstly, a substrate made of quartz glass was prepared as an object to be processed. Further, a coating liquid containing a catalytic material was prepared. An i-line resist was used as the catalytic material, and the coating liquid was prepared by mixing the i-line resist with solvents (ethyl lactate and n-butyl acetate).

The used i-line resist contains a novolak resin represented by the below-shown chemical formula.

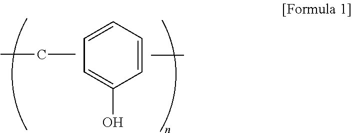

Therefore, the i-line resist contains a hydroxy group as the polar functional group.

Next, a coating liquid was placed, i.e., applied, on the first surface of the substrate by a spin coating method.

Next, a pattern of the catalytic material consisting of a plurality of lines was set on the first surface of the substrate by gray-scale exposure and the subsequent developing process.

FIG. 17 schematically shows the cross section of the formed catalytic material.

As shown in FIG. 17, the catalytic material 430 has a rectangular cross section obtained by, for example, rotating a trapezoid by 90°. That is, the catalytic material 430 includes a first side surface 417A and a second side surface 417B opposed to each other, and includes a top surface 418.

The distance between the first and second side surfaces 417A and 417B, i.e., the width W, is 10 μm. Further, the height H1 of the first side surface 417A is about 1.0 μm, and the height H2 of the second side surface 417B is about 0.5 μm. The inclination angle of the top surface 418, i.e., the angle θr, is 2.9°.

Next, the catalytic material was irradiated with irradiation light by using a low-pressure mercury lamp (hereinafter referred to as “Lamp A”).

Lamp A was a DUV lamp having a main wavelength of 254 nm, and the irradiation amount P for the catalytic material was 72,000 mJ/cm².

Next, the substrate was cut into a piece having a size of about 10 mm× about 10 mm, and the cut sample was placed in a processing chamber in such a manner that the catalytic material faces upward. Further, a gas etching process was performed on the sample in the processing chamber. A mixed gas of a nitrogen gas and a hydrogen fluoride gas (HF/N₂=20 vol %) was used as the processing gas. The processing temperature was 250° C., and the processing time was 40 minutes.

After the etching process, a recess structure was formed on the surface. The obtained object to be processed is referred to as “Sample 1”.

### Example 2

A recessed structure(s) was formed in the first surface of a substrate by a method similar to that in Example 1. However, in Example 2, the recess structure(s) was formed by using a catalytic material(s) of which the shape had been changed from that in Example 1. Specifically, in FIG. 17, the inclination angle θr of the top surface 418 was set to 5.7°, and the height H2 of the second side surface 417B was set to 0. Therefore, the cross section of the catalytic material was triangular.

After the etching process, a recess structure was formed on the surface. The obtained object to be processed is referred to as “Sample 2”.

### Example 3

A recessed structure(s) was formed in the first surface of a substrate by a method similar to that in Example 2. However, in Example 3, unlike Example 2, the irradiation amount of the irradiation light was set to 144,000 mJ/cm².

After the etching process, a recess structure was formed on the surface. The obtained object to be processed is referred to as “Sample 3”.

### Example 4

A recessed structure(s) was formed in the first surface of a substrate by a method similar to that in Example 1. However, in Example 4, the recess structure(s) was formed by using a catalytic material(s) of which the shape had been changed from that in Example 1. Specifically, in FIG. 17, the inclination angle θr of the top surface 418 was set to 11.3°, and the height H2 of the second side surface 417B was set to 0. Therefore, the cross section of the catalytic material was triangular. Further, the width of the catalytic material was 5 μm.

However, in Example 4, the recess structure(s) was formed with the irradiation amount P of the irradiation light different from that in Example 1.

After the etching process, a recess structure was formed on the surface. The obtained object to be processed is referred to as “Sample 4”.

### (Evaluation)

In each sample, a cross section of the recess structure was observed by a scanning electron microscope (SEM), and various dimensions of the recess structure were measured. In particular, the angle α_{b} and the ratio P2/P1 of the recess structure, which are defined as described above, were measured.

The manufacturing conditions for the samples and their evaluation results are summarized in Table 1 shown below.

TABLE 1

| | Catalytic material | | | |
|---|---|---|---|---|
| | Cross-sectional | | | Irradiation |
| Sample | shape | Width (μm) | Angle θr (°) | amount (mJ/cm²) |
| 1 | Rectangle | 10 | 2.9 | 7200 |
| 2 | Triangle | 10 | 5.7 | 7200 |
| 3 | Triangle | 10 | 5.7 | 144000 |
| 4 | Triangle | 5 | 11.3 | 72000 |

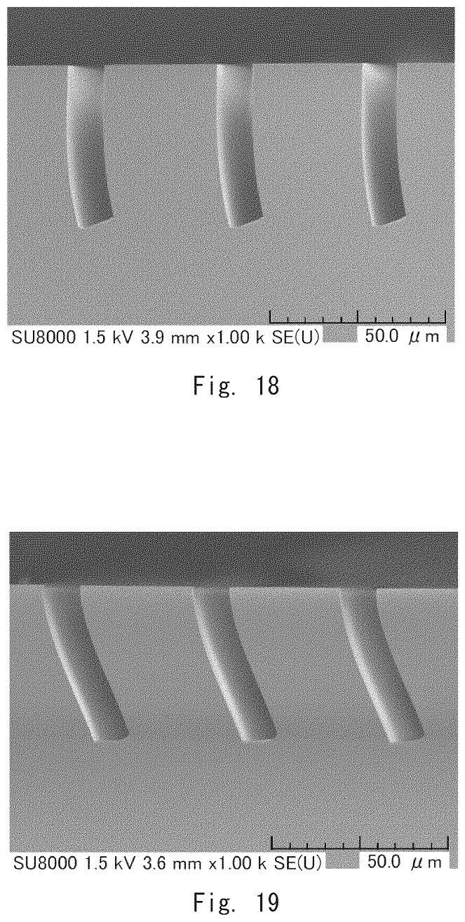

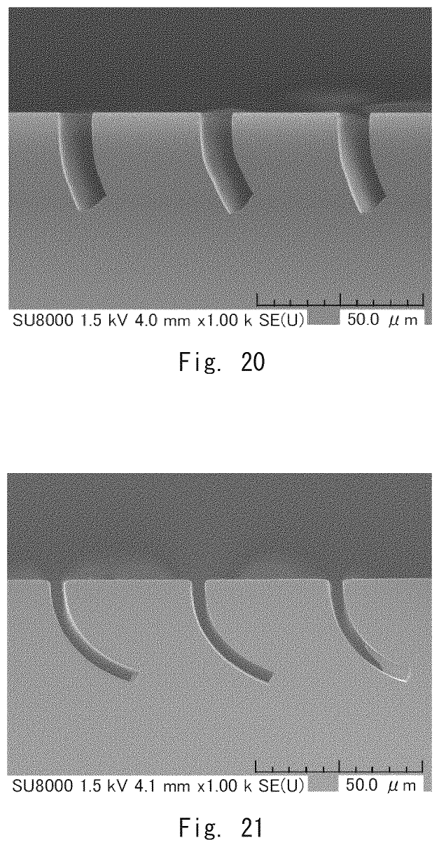

FIGS. 18 to 21 show examples of cross sections of the recess structures obtained in Samples 1 to 4, respectively.

As shown in these drawings, it can be seen that a recess structure inclined to the right is formed in each of the samples. In particular, the curvature of the recess structure is noticeable in Samples 1, 3 and 4.

Further, as shown in Table 1, the ratio P2/P1 is very close to 1 in each sample. Based on this fact, it can be seen that the recess structure formed in each sample has a form having a substantially constant cross-sectional shape along the extending direction.

### EMBODIMENTS OF PRESENT INVENTION

The present invention includes embodiments described below.

### Embodiment 1

A method for manufacturing a member with a recess structure, comprising:
(1) a step of placing a catalytic material in a first area on a first surface of an object to be processed, in which
the first surface is made of an element of which a boiling point of a fluoride is 550° C. or lower,
the catalytic material contains an organic compound containing a polar functional group, and
the catalytic material includes, in a cross-sectional view of the catalytic material, i.e., in cross section perpendicular to the first surface, a first side surface having a first height H1 and a second side surface having a second height H2, the first and second side surfaces being opposed to each other, in which H1>0 μm, H2>0 μm, and the height H1 is higher than the height H2:
(2) a step of irradiating the catalytic material with irradiation light containing deep ultraviolet light having a wavelength of 380 nm or shorter; and
(3) a step of exposing the object to be processed to a fluorine-containing gas at 80° C. or higher, wherein
a recess structure is formed below the first area after the step (3), and the recess structure has, in the cross-sectional view, at a center of the first area, a shape inclined toward the second side surface from a perpendicular line dropped from the first surface.

### Embodiment 2

The method described in Embodiment 1, wherein in the step 1, in the catalytic material, in the cross-sectional view, an angle φ (0°<φ<90°) formed between a straight line connecting uppermost parts of the first and second side surfaces and the first surface is within a range of 1° to 80°.

### Embodiment 3

The method described in Embodiment 1 or 2, wherein the catalytic material has a width of 0.1 μm to 100 μm in the cross-sectional view.

### Embodiment 4

The method described in any one of Embodiments 1 to 3, wherein the catalytic material includes a top surface of which a height monotonically lowers from the first side surface to the second side surface in the cross-sectional view.

### Embodiment 5

The method described in any one of Embodiments 1 to 4, wherein the catalytic material is rectangular or triangular in the cross-sectional view.

### Embodiment 6

The method described in any one of Embodiments 1 to 5, wherein the polar functional group contains at least one group or bond selected from the group consisting of a hydroxy group, an aldehyde group, a carboxy group, an amino group, a sulfo group, a thiol group, an amide bond, a carbonyl group, a nitro group, a cyano group, an ether bond, and an ester bond.

### Embodiment 7

The method described in any one of Embodiments 1 to 6, wherein the fluorine-containing gas is a hydrogen fluoride gas or a fluorine gas.

### Embodiment 8

The method described in any one of Embodiments 1 to 7, wherein the step (3) is carried out in a range of 200° C. to 450° C.

### Embodiment 9

The method described in any one of Embodiments 1 to 8, wherein the first surface contains at least one element selected from the group consisting of H, B, C, N, O, Si, P, S, CI, Ti, V, Cr, Ge, As, Se, Br, Nb, Mo, Tc, Ru, Rh, Sn, Sb, Te, I, Ta, W, Re, Os, Ir, Pt, and Au.

### Embodiment 10

The method described in any one of Embodiments 1 to 9, wherein the object to be processed is formed of one member.

### Embodiment 11

The method described in Embodiment 10, wherein the object to be processed contains SiO₂.

### Embodiment 12

The method described in any one of Embodiments 1 to 9, wherein the object to be processed comprises one or two or more layers.

### Embodiment 13

A member with a recess structure on a first surface, wherein the first surface contains at least one element selected from the group consisting of B, C, Si, P, S, Ti, V, Cr, Ge, As, Se, Nb, Mo, Tc, Ru, Rh, Sn, Sb, Te, I, Ta, W, Re, Os, Ir, Pt, and Au,
the recess structure comprises an opening formed in the first surface, a bottom surface, and a sidewall connecting the opening and the bottom surface,
the recess structure has a curved shape in a cross-sectional view of the catalytic material, i.e., in cross section perpendicular to the first surface,
a ratio P2/P1 of a size P2 of the bottom surface to a size P1 of the opening is in a range of 0.99 or larger, and smaller than 1.1, and
a center of the bottom surface is deviated from an extension axis extending from a center of the opening in a direction perpendicular to the first surface.

### Embodiment 14

The member described in Embodiment 13, wherein a surface of the sidewall includes at least one streak extending from the opening to the bottom surface.

### Embodiment 15

The member described in Embodiment 13 or 14, wherein the recess structure has a depth of 10 μm or deeper.

### Embodiment 16

The member described in any one of Embodiments 13 to 15, wherein in the recess structure, an angle α (0°<α<180°) of the sidewall with respect to a plane parallel to the first surface continuously changes from the opening to the bottom surface.

### Embodiment 17

The member described in any one of Embodiments 13 to 16, wherein the recess structure has such a curved shape that a center of the opening and a center of the bottom surface cannot be connected by a straight line.

### Embodiment 18

The member described in any one of Embodiments 13 to 17, wherein the first surface further contains at least one element selected from the group consisting of H, N, CI, Br, and O.

### Embodiment 19

The member described in any one of Embodiments 13 to 18, wherein the member is formed of one member.

### Embodiment 20

The member described in Embodiment 19, wherein the member is a quartz glass substrate or a crystal substrate.

### Embodiment 21

The member described in any one of Embodiments 13 to 18, wherein the member comprises one or two or more layers.

### Embodiment 22

The member described in any one of Embodiments 13 to 18, wherein the member comprises a substrate and a film disposed on the substrate, and the film contains at least one of SiO₂, SiN, and SiC and forms the first surface.

These embodiments can be combined as desirable by one of ordinary skill in the art. From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A method for manufacturing a member with a recess structure, comprising:
(1) a step of placing a catalytic material in a first area on a first surface of an object to be processed, in which
the first surface is made of an element of which a boiling point of a fluoride is 550° C. or lower,
the catalytic material contains an organic compound containing a polar functional group, and
the catalytic material includes, in a cross-sectional view of the catalytic material, i.e., in cross section perpendicular to the first surface, a first side surface having a first height H1 and a second side surface having a second height H2, the first and second side surfaces being opposed to each other, in which H1>0 μm, H2>0 μm, and the height H1 is higher than the height H2:
(2) a step of irradiating the catalytic material with irradiation light containing deep ultraviolet light having a wavelength of 380 nm or shorter; and
(3) a step of exposing the object to be processed to a fluorine-containing gas at 80° C. or higher, wherein
a recess structure is formed below the first area after the step (3), and the recess structure has, in the cross-sectional view, at a center of the first area, a shape inclined toward the second side surface from a perpendicular line dropped from the first surface.

2. The method according to claim 1, wherein in the step 1, in the catalytic material, in the cross-sectional view, an angle φ ((0°<φ<90°) formed between a straight line connecting uppermost parts of the first and second side surfaces and the first surface is within a range of 1° to 80°.

3. The method according to claim 1, wherein the catalytic material has a width of 0.1 μm to 100 μm in the cross-sectional view.

4. The method according to claim 1, wherein the catalytic material includes a top surface of which a height monotonically lowers from the first side surface to the second side surface in the cross-sectional view.

5. The method according to claim 1, wherein the catalytic material is rectangular or triangular in the cross-sectional view.

6. The method according to claim 1, wherein the polar functional group contains at least one group or bond selected from the group consisting of a hydroxy group, an aldehyde group, a carboxy group, an amino group, a sulfo group, a thiol group, an amide bond, a carbonyl group, a nitro group, a cyano group, an ether bond, and an ester bond.

7. The method according to claim 1, wherein the fluorine-containing gas is a hydrogen fluoride gas or a fluorine gas.

8. The method according to claim 1, wherein the step (3) is carried out in a range of 200° C. to 450° C.

9. The method according to claim 1, wherein the first surface contains at least one element selected from the group consisting of H, B, C, N, O, Si, P, S, Cl, Ti, V, Cr, Ge, As, Se, Br, Nb, Mo, Tc, Ru, Rh, Sn, Sb, Te, I, Ta, W, Re, Os, Ir, Pt, and Au.

10. The method according to claim 1, wherein the object to be processed is formed of one member.

11. The method according to claim 10, wherein the object to be processed contains SiO₂.

12. The method according to claim 1, wherein the object to be processed comprises one or two or more layers.

13. A member with a recess structure on a first surface, wherein
the first surface contains at least one element selected from the group consisting of B, C, Si, P, S, Ti, V, Cr, Ge, As, Se, Nb, Mo, Tc, Ru, Rh, Sn, Sb, Te, I, Ta, W, Re, Os, Ir, Pt, and Au,
the recess structure comprises an opening formed in the first surface, a bottom surface, and a sidewall connecting the opening and the bottom surface,
the recess structure has a curved shape in a cross-sectional view of the catalytic material, i.e., in cross section perpendicular to the first surface,
a ratio P2/P1 of a size P2 of the bottom surface to a size P1 of the opening is in a range of 0.99 or larger, and smaller than 1.1, and
a center of the bottom surface is deviated from an extension axis extending from a center of the opening in a direction perpendicular to the first surface.

14. The member according to claim 13, wherein a surface of the sidewall includes at least one streak extending from the opening to the bottom surface.

15. The member according to claim 13, wherein the recess structure has a depth of 10 μm or deeper.

16. The member according to claim 13, wherein in the recess structure, an angle α (0°<α<180° of the sidewall with respect to a plane parallel to the first surface continuously changes from the opening to the bottom surface.

17. The member according to claim 13, wherein the recess structure has such a curved shape that a center of the opening and a center of the bottom surface cannot be connected by a straight line.

18. The member according to claim 13, wherein the first surface further contains at least one element selected from the group consisting of H, N, Cl, Br, and O.

19. The member according to claim 13, wherein the member is formed of one member.

20. The member according to claim 19, wherein the member is a quartz glass substrate or a crystal substrate.
